(19) United States
(12) Patent Application Publication
(10) Pub. No.: US 2023/0052879 A1
(43) Pub. Date: Feb. 16, 2023

(54) SEMICONDUCTOR LIGHT-EMITTING DEVICE

(71) Applicant: SL VIONICS CO., LTD., Gyeonggi-do (KR)

(72) Inventors: Sung Gi LEE, Gyeonggi-do (KR); Soo Kun JEON, Gyeonggi-do (KR); Jun Chun PARK, Gyeonggi-do (KR); Sung Gyu LEE, Gyeonggi-do (KR)

(21) Appl. No.: 17/790,178

(22) PCT Filed: Mar. 26, 2021
(86) PCT No.: PCT/KR2021/003799

§ 371 Date: Jun. 30, 2022

(30) Foreign Application Priority Data
Mar. 26, 2020 (KR) 10-2020-0036768

(51) Int. Cl. H01L 33/08; H01L 33/38; H01L 33/62

(52) U.S. Cl. CPC H01L 33/08; H01L 33/38; H01L 33/62

(57) ABSTRACT

The present disclosure relates to a semiconductor light emitting device comprising: a growth substrate; a first semiconductor layer; a first light emitting part, including an active layer which is provided on the first semiconductor layer and generates ultraviolet light, and a second semiconductor layer; a second light emitting part, including an active layer which is provided on the first semiconductor layer and generates ultraviolet light, and a second semiconductor layer; a connecting part which is provided on the first semiconductor layer and connects the first light emitting part and the second light emitting part; an insulating layer that covers the first semiconductor layer, the first light emitting part, the second light emitting part and the connecting part; a first pad electrode which is formed on the insulating layer; and a second pad electrode which is formed on the insulating layer.

### TECHNICAL FIELD

This disclosure relates generally to a semiconductor light emitting device. In particular, it relates to a semiconductor light emitting device having an increased efficiency of light emission.

In the context herein, the term “semiconductor light emitting device” refers to a semiconductor optoelectronic device which generates light by electron-hole recombination. One example thereof is Group III-nitride semiconductor light emitting devices (LED, LD), in which the Group III-nitride semiconductor is composed of a compound containing Al(x)Ga(y)In(1-x-y)N (0≤x≤1, 0≤y≤1, 0≤x+y≤1). Another example thereof is GaAs-based semiconductor light emitting devices used for emitting red light.

### BACKGROUND

This section provides background information related to the present disclosure which is not necessarily prior art. Directional terms, such as “upper”, “lower”, “above”, “below” or others used herein are defined with respect to the directions in the drawings.

FIG. 1 shows an example of a semiconductor light emitting device in the art.

The semiconductor light emitting device includes a growth substrate 10 (e.g. a sapphire substrate), and a stack of semiconductor layers sequentially deposited on the growth substrate 10, including a buffer layer 20, a first semiconductor layer 30 having a first conductivity (e.g. an n-type GaN layer), an active layer 40 for generating light by electron-hole recombination (e.g. an InGaN/(In)/GaN multiple quantum well (MQW) structure), and a second semiconductor layer 50 having a second conductivity different from the first conductivity (e.g. a p-type GaN layer). The buffer layer 20 can be omitted. The semiconductor light emitting device further includes a light transmitting conductive film 60 for current spreading formed on the second semiconductor layer 50, an electrode 70 serving as a bonding pad formed on the light transmitting conductive film 60, and an electrode 80 serving as a bonding pad (e.g. a stack of Cr/Ni/Au metallic pads) formed on an etched exposed portion of the first semiconductor layer 30. This particular type of the semiconductor light emitting device as shown in FIG. 1 is called a lateral chip. Here, one side of the growth substrate 10 serves as a mounting face during electrical connections to outside.

FIG. 2 shows another example of a semiconductor light emitting device disclosed in U.S. Pat. No. 7,262,436. For convenience of description, similar components may have same or different reference numerals.

In this semiconductor light emitting device chip, there is provided a growth substrate 10, and a stack of layers sequentially deposited on the growth substrate 10, including a first semiconductor layer 30 having a first conductivity, an active layer 40 adapted to generate light by electron-hole recombination and a second semiconductor layer 50 having a second conductivity different from the first conductivity. Three-layered electrode films 90, 91 and 92 adapted to reflect light towards the growth substrate 10 are then formed on the second semiconductor layer 50, in which a first electrode film 90 can be a reflecting Ag film, a second electrode film 91 can be a Ni diffusion barrier, and a third electrode film 92 can be an Au bonding layer. Further, an electrode 80 serving as a bonding pad is formed on an etched exposed portion of the first semiconductor layer 30. Here, one side of the electrode film 92 serves as a mounting face during electrical connections to outside. This particular type of the semiconductor light emitting device chip as shown in FIG. 2 is called a flip chip. In this flip chip of FIG. 2, the electrode 80 formed on the first semiconductor layer 30 is placed at a lower height level than the electrode films 90, 91 and 92 formed on the second semiconductor layer 50, but as an alternative, it may be formed at the same height level as the electrode films. Here, height levels are given with respect to the growth substrate 10. Examples of the semiconductor light emitting device may include a lateral chip, a vertical chip, and a flip chip.

FIG. 3 shows another example of a semiconductor light emitting device disclosed in Korean Patent Application Laid-Open No. 2015-0055390. For convenience of description, similar components may have same or different reference numerals.

The semiconductor light emitting device is a flip chip, which includes a growth substrate 10 (e.g. a sapphire substrate), and a stack of semiconductor layers sequentially deposited on the growth substrate 10, including a buffer layer 20, a first semiconductor layer 30 having a first conductivity (e.g. an n-type semiconductor layer), an active layer 40 for generating light by electron-hole recombination (e.g. an InGaN/(In)/GaN MQWs), and a second semiconductor layer 50 having a second conductivity different from the first conductivity (e.g. a p-type semiconductor layer). The buffer layer 20 can be omitted. The semiconductor light emitting device further includes a light transmitting conductive film 60 for current spreading formed on the second semiconductor layer 50, a second pad electrode 70 serving as a bonding pad, and a first pad electrode 80 (e.g., a stack of Cr/Ni/Au metallic pads) electrically connected to the etched-exposed first semiconductor layer 30, thereby serving as a bonding pad. Moreover, a first electrode 51 formed on the first semiconductor layer (the n-type semiconductor layer) and a second electrode 52 formed on the second semiconductor layer (the p-type semiconductor layer) are provided as ohmic electrodes for lowering the operating voltage of the semiconductor light emitting device. The semiconductor light emitting device also includes an insulation layer 93.

FIG. 4 shows another example of a semiconductor light emitting device disclosed in Korean Patent Application Publication No. 2014-0073160. For convenience of description, similar components may have same or different reference numerals.

As shown, a first semiconductor layer 30 is formed on a growth substrate 10, and an active layer 40 and a second semiconductor layer 50 are placed on the first semiconductor layer 30. A plurality of light emitting units M is formed on the first semiconductor layer 30, being spaced apart from each other. Each of the plurality of light emitting units M can include the active layer 40 and the second semiconductor layer 50. The active layer 40 is positioned between the first semiconductor layer 30 and the second semiconductor layer 50. Ohmic electrodes 90 and 92 are disposed on the plurality of light emitting units M, respectively. When seen in the plan view as in FIG. 4A, the second semiconductor layer 50 and the active layer 40 are formed by dry or wet etching in a manner that they are surrounded by the first semiconductor layer 30.

A semiconductor ultraviolet light emitting device has been under active development. In general, such a device includes a plurality of semiconductor layers based on an aluminum gallium nitride (AlGaN) material. However, the AlGaN material has a high sheet resistance, leading to poor current spreading. In addition, ultraviolet light having a shorter wavelength is absorbed by the second semiconductor layer, the ohmic electrodes and the pad electrodes, which results in an increased temperature as well as a lower light emission of the semiconductor light emitting device.

Thus, the present disclosure is directed to provide a semiconductor light emitting device configured to increase the light emission efficiency of ultraviolet light with a shorter wavelength.

### SUMMARY

The present invention is specified in the below description.

This section provides a general summary of the disclosure and is not a comprehensive disclosure of its full scope or all of its features.

According to one aspect, there is provided a semiconductor light emitting device, A semiconductor light emitting device comprising: a growth substrate; a first semiconductor layer which is provided on the growth substrate and has a first conductivity; a first light emitting part, including an active layer which is provided on the first semiconductor layer and generates ultraviolet light by electron-hole recombination, and a second semiconductor layer which is provided on the active layer and has a second conductivity different from the first conductivity; a second light emitting part, including an active layer which is provided on the first semiconductor layer and generates ultraviolet light by electron-hole recombination, and a second semiconductor layer which is provided on the active layer and has a second conductivity different from the first conductivity; a connecting part, including an active layer which is provided on the first semiconductor layer and generates ultraviolet light by electron-hole recombination, and a second semiconductor layer which is provided on the active layer and has a second conductivity different from the first conductivity, with the connecting part connecting the first light emitting part and the second light emitting part; an insulating layer that covers the first semiconductor layer, the first light emitting part, the second light emitting part and the connecting part; a first pad electrode which is formed on the insulating layer and is electrically connected to the first semiconductor layer; and a second pad electrode which is formed on the insulating layer and is electrically connected to the second semiconductor layer, wherein, in a plan view, part of the connecting part does not overlap with the first pad electrode and the second pad electrode, and the connecting part has a width smaller than the widths of first light emitting part and the second light emitting part.

Various features and advantages of the invention will be described in further detail below.

### BRIEF DESCRIPTION OF THE DRAWINGS

FIG. 1 shows an example of a semiconductor light emitting device in the art.

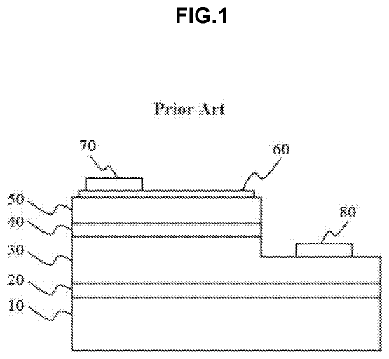

FIG. 2 shows another example of a semiconductor light emitting device disclosed in U.S. Pat. No. 7,262,436.

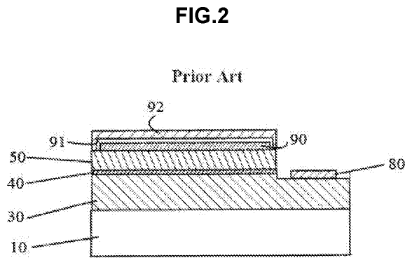

FIG. 3 shows another example of a semiconductor light emitting device disclosed in Korean Patent Application Publication No. 2015-0055390.

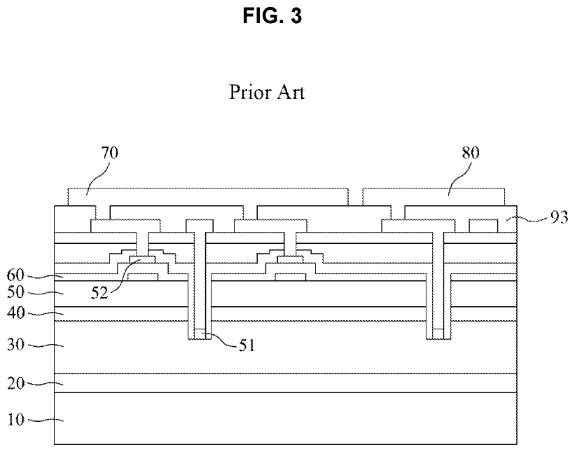

FIG. 4 shows another example of a semiconductor light emitting device disclosed in Korean Patent Application Publication No. 2014-0073160.

FIG. 5 shows an exemplary embodiment of a semiconductor light emitting device according to the present disclosure.

FIG. 6 shows another exemplary embodiment of a semiconductor light emitting device according to the present disclosure.

FIG. 7 shows an exemplary embodiment of a method for manufacturing a semiconductor light emitting device according to the present disclosure.

### DETAILED DESCRIPTION

The present disclosure will now be described in detail with reference the accompanying drawing(s). Directional terms, such as “upper”, “lower”, “above”, “below” or others used herein are defined with respect to the directions in the drawings.

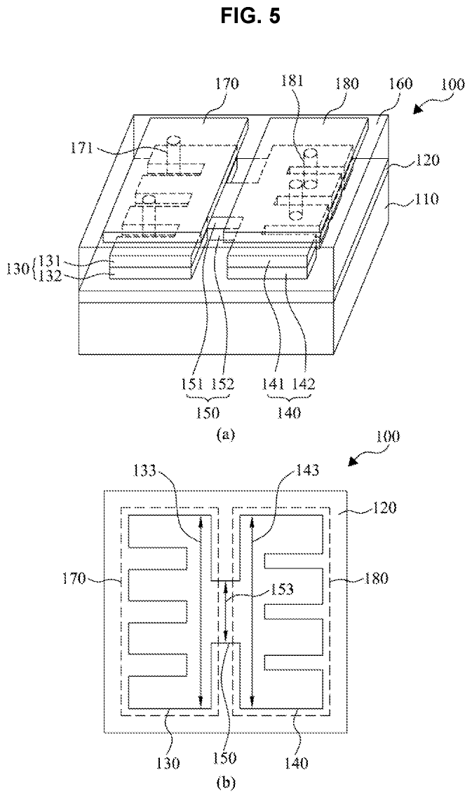

FIG. 5 shows an exemplary embodiment of a semiconductor light emitting device according to the present disclosure.

FIG. 5A is a perspective view, and FIG. 5B is a plan view. For convenience of description, some parts that are not actually visible from outside are included in the drawings.

The semiconductor light emitting device 100 includes a growth substrate 110, a first semiconductor layer 120 having a first conductivity, a first light emitting part 130, a second light emitting part 140, a connecting part 150, an insulating layer 160, a first pad electrode 170 and a second pad electrode 180.

The growth substrate 110 may be made of a material such as sapphire (Al₂O₃), SiC, Si or GaAs, and its material is not particularly limited as far as it can grow semiconductor thereon.

The first semiconductor layer 120 is a semiconductor layer having a first conductivity and may be an N-type semiconductor layer, for example.

The first light emitting part 130 includes an active layer 132 which is provided on the first semiconductor layer 120 and generates ultraviolet light through electron-hole recombination, and a second semiconductor layer 131 which is provided on the active layer 132 and has a second conductivity different from the first conductivity. The second semiconductor layer 131 may be a P-type semiconductor layer, for example.

The second light emitting part 140 includes an active layer 142 which is provided on the first semiconductor layer 120 and generates ultraviolet light through electron-hole recombination, and a second semiconductor layer 141 which is provided on the active layer 142 and has a second conductivity different from the first conductivity. The second semiconductor layer 141 may be a P-type semiconductor layer, for example.

The connecting part 150 is positioned between the first light emitting part 130 and the second light emitting part 140 to connect the first light emitting part 130 and the second light emitting part 140. Further, the first connecting part 150 includes an active layer 152 which is provided on the first semiconductor layer 120 and generates ultraviolet light through electron-hole recombination, and a second semiconductor layer 151 which is provided on the active layer 152 and has a second conductivity different from the first conductivity. The second semiconductor layer 151 may be a P-type semiconductor layer, for example. The connecting part 150 serves as a passage that electrically connects the first light emitting part 130 and the second light emitting part 140, and it also emits ultraviolet light through the active layer 152.

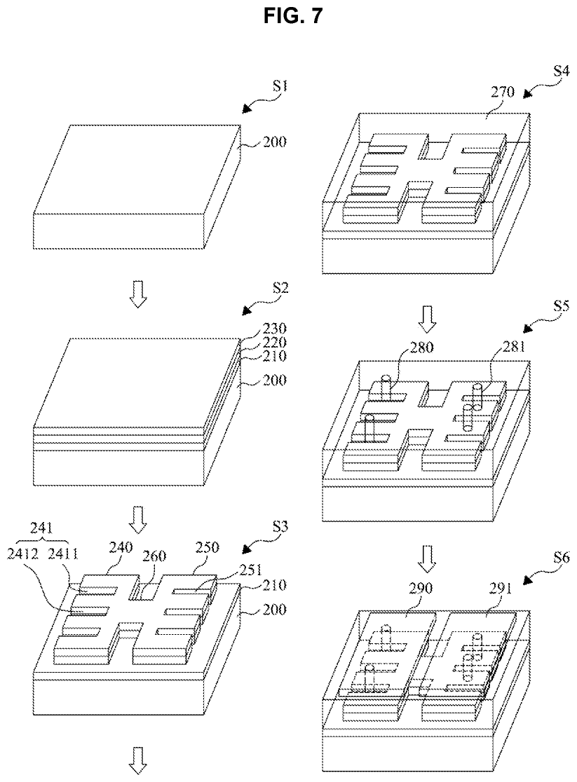

The first semiconductor layer 120, the active layers 132, 142 and 152, and the second semiconductor layers 131, 141 and 151 are particularly AIGaN-based semiconductor layers that are grown on the growth substrate 110 and can emit ultraviolet light. After the first semiconductor layer 120, the active layers 132, 142 and 152, and the second semiconductor layers 131, 141 and 151 are sequentially grown on the growth substrate 110, dry or wet etching may be performed to form the first light emitting part 130, the second light emitting part 140 and the connecting part 150 can be formed. A relevant manufacturing method will be described later with reference to FIG. 7.

The insulating layer 160 covers the first semiconductor layer 120, the first light emitting part 130, the second light emitting part 140, and the connecting part 150. The insulating layer 160 may be made of SiO₂. Alternatively, the insulating layer 160 may be made of SiN, TiO₂, Al₂O₃, Su-8, or the like. Further, in order to increase the amount of reflection of light, the insulating layer 160 may have a dielectric multi-layer structure including, for example, a DBR (Distributed Bragg Reflector comprised of a combination of SiO₂ and TiO₂) or an ODR (Omni-Directional Reflector).

The first pad electrode 170 and the second pad electrode 180 are formed on the insulating layer 160, in which the first pad electrode 170 is electrically connected to the first semiconductor layer 120 through a via hole (or through hole) 171 running through the insulating layer 160, and the second pad electrode 180 is electrically connected to the second semiconductor layer 142 through a via hole 181 running through the insulating layer 160. The first pad electrode 170 and the second pad electrode 180 each serve as a bonding pad and can be a stack of Cr/Ni/Au metallic pads, for example.

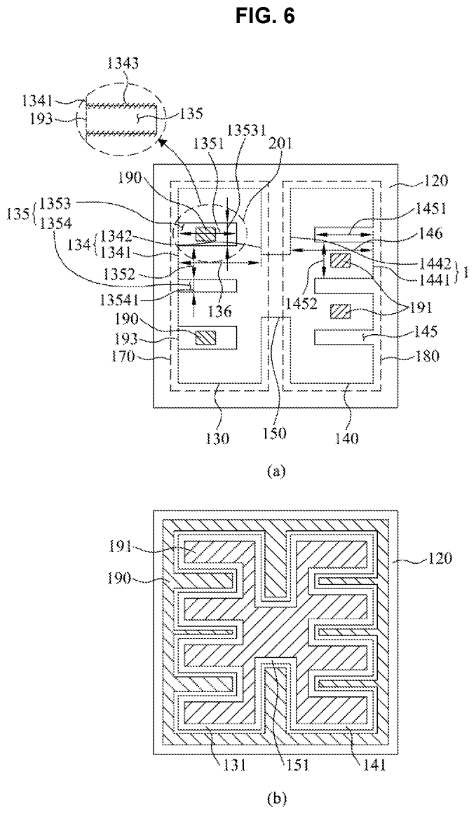

Referring to the plan view FIG. 5B, the connecting part 150 is positioned between the first pad electrode 170 and the second pad electrode 180 indicated by dotted lines, such that at least part of the connecting part 150 does not overlap with the first pad electrode 170 and the second pad electrode 180 in a plan view. The first pad electrode 170 and the second pad electrode 180 can absorb ultraviolet light having a shorter wavelength. The active layer 150 of the connecting part 150 (as aforementioned, at least part of the connecting part 150 does not overlap with the first pad electrode 170 and the second pad electrode 180 in a plan view) emits light, but because a small amount of the light from the active layer 150 would be absorbed by the first pad electrode 170 and the second pad electrode 180, it might seem desirable that the connecting part 150 has a greater width 153. However, it was discovered through an experiment that heat from the connecting part 150 is not well discharged if the connecting part 150 has a greater width 153, and this lowers the luminous efficiency of the semiconductor light emitting device. That is, it may be a problem that the first pad electrode 170 and the second pad electrode 180 absorb ultraviolet light, but it is another problem that heat is discharged outside through the first pad electrode 170 and the second pad electrode 180, meaning that the heat generated in the connecting part not overlapping with the first pad electrode 170 and the second pad electrode 180 would not be discharged. In particular, it was again discovered through an experiment that a decrease in the luminous efficiency of the semiconductor light emitting device due to the heat that is not discharged through the first and second pad electrodes 170 and 180 is more problematic than a decrease in the luminous efficiency due to the heat that is generated as the first and second pad electrodes 170 and 180 absorb ultraviolet light. The present disclosure resolved this problem by making the width 153 of the connecting part 150 (i.e., at least part of it does not overlap with the first pad electrode 170 and the second pad electrode 180 in a plan view) smaller than the widths 133 and 143 of the first and second light emitting parts 130 and 140, such the luminous efficiency of the semiconductor light emitting device may not be affected by the heat generated in the connecting part 150. Preferably, the width 153 of the connecting part 150 is 160 μm or less. According to an experimental result, if the width 153 of the connecting part 150 is greater than 160 μm, the heat generated in the connecting part 150 is not discharged and hence the luminous efficiency is still lowered. Further, referring to FIG. 6B, if a distance between the center of the connecting part and the first ohmic electrode 190 formed on the second semiconductor layer 120 between the first light emitting part 130 and the second light emitting part 140 increases, current is not well spread and hence, the luminous efficiency at the center of the connecting part 150 may be lowered. Moreover, if the width 153 of the connecting part 150 is smaller than 50 μm, current spreading between the first light emitting part 130 and the second light emitting part 140 through the connecting part 150 is decreased. Therefore, it is desirable that the width 153 of the connecting part 150 is at least 50 μm.

FIG. 6 shows another exemplary embodiment of a semiconductor light emitting device according to the present disclosure.

For convenience in description, only plan views are provided.

Referring to FIG. 6A, each of the first light emitting part 130 and the second light emitting part 140 includes a lateral surface 134, 144. The lateral surface 134, 144 of each of the first light emitting part 130 and the second light emitting part 140 includes an inner lateral surface 1342, 1442 positioned in the direction of the connecting part 150 and an outer lateral surface 1341, 1441 facing the inner lateral surface 1342, 1442. In a plan view, at least one of the lateral surfaces 1341, 1342, 1441 and 1442 of the lateral surfaces 134 and 144 of the first and second light emitting parts 130 and 140 can have a plurality of grooves 135 and 145 through which the first semiconductor layer 120 is exposed. Because light is generated by the active layer, it is desirable to make the active layer wide. However, in the case of the semiconductor light emitting device that emits ultraviolet light having a shorter wavelength, when the ultraviolet light from the active layer escapes through the top, the amount of the ultraviolet light absorbed by the P-type semiconductor layers (i.e., the second semiconductor layer and the pad electrode) is greater that that of the semiconductor light emitting device that emits visible light. As such, the ultraviolet light escaping through the lateral surfaces of the light emitting parts 130 and 140 is crucial in terms of the luminous efficiency, and it is desirable to form the lateral surfaces of the light emitting parts 130 and 140 wide. In the present disclosure, the lateral surfaces 134 and 144 of the first and second light emitting parts 130 and 140 are not formed into those indicated by dotted lines 193 and the first semiconductor layer 120 includes the plurality of grooves 135 and 145 exposed, so that more lateral surfaces can be formed on the plane. For example, as can be seen from an enlarged view in a dotted circle 201, the lateral surface 1341 of the first light emitting part 130 forms more grooves 135 by a hatched portion 1343, as compared with the lateral surface 1341 formed by connecting lines such as the dotted line 193. Moreover, the plurality of grooves 135 and 145 has a depth 1351, 1451 that ranges between ½ and ⅔ of a width 136, 146 of the first and second light emitting part 130 and 140. If the depth 1351, 1451 of the groove 135, 145 is smaller than ½ of the width 136, 146 of the first and second light emitting parts 130 and 140, the luminous efficiency of ultraviolet light through the lateral surfaces may be lowered. In addition, in order to reduce the operating voltage of the semiconductor device 100, the first ohmic electrode 190 may be formed in the first semiconductor layer 120, and the second ohmic electrode 191 may be formed in the second semiconductor layer 142. If the depth 1351, 1451 of the groove 135, 145 is smaller than ½ of the width 136, 146 of the first and second light emitting parts 130 and 140, the first ohmic electrode 190 formed within the groove 135, 145 may get further from the center of each the light emitting part 130, 140 increases and hence, current may not spread to the center of each light emitting part 130, 140. On the contrary, if the depth 1351, 1451 of the groove 135, 145 is greater than ⅔ of the width 136, 146 of the first and second light emitting parts 130 and 140, the active region is reduced and hence, the luminous efficiency of ultraviolet light can be lowered. Also, gaps 1352 and 1452 between the plurality of grooves 135 and 145 are preferably uniform. In particular, when the first ohmic electrode 190 is formed within the plurality of grooves 135 and 145, the gaps 1352 and 1452 between the plurality of grooves 135 and 145 are preferably smaller than ½ of the widths 136 and 146 of the first and second light emitting parts 130 and 140, in order to resolve the problem of the current not spreading as the center of each light emitting part 130, 140 gets farther from the first ohmic electrode 190.

For current spreading, the first ohmic electrode 190 is preferably positioned in the plurality of grooves 135 and 145. For instance, as shown in FIG. 6, the first ohmic electrode 190 can be positioned in the groove 135 of the first light emitting part. In this case the groove 1353 in which the first ohmic electrode 190 is placed has a width 13531 greater than a width 13541 of another groove 1354 in which the first ohmic electrode 190 is not placed. This will be explained in further detail with reference to FIG. 7. A first pad electrode 170 is preferably provided on the first ohmic electrode 190. In this way, the first ohmic electrode 190 and the first pad electrode 170 can be electrically connected in a simple structure. In the present disclosure, the first ohmic electrode 190 is positioned in the groove 1353 of the first light emitting part 130, and the first pad electrode 170 is formed such that it overlaps with the first light emitting part 130 in a plan view. Thus, the second ohmic electrode 191 is formed on the second semiconductor layer 142 of the second light emitting part 140, and the second pad electrode 180 is formed such that it overlaps with the second light emitting part 140 in a plan view. To facilitate heat discharge through the first and second pad electrodes 170 and 180, in a plan view, the entire first light emitting part 130 preferably overlaps with the first pad electrode 170 and the entire second light emitting part 140 preferably overlaps with the second pad electrode 180.

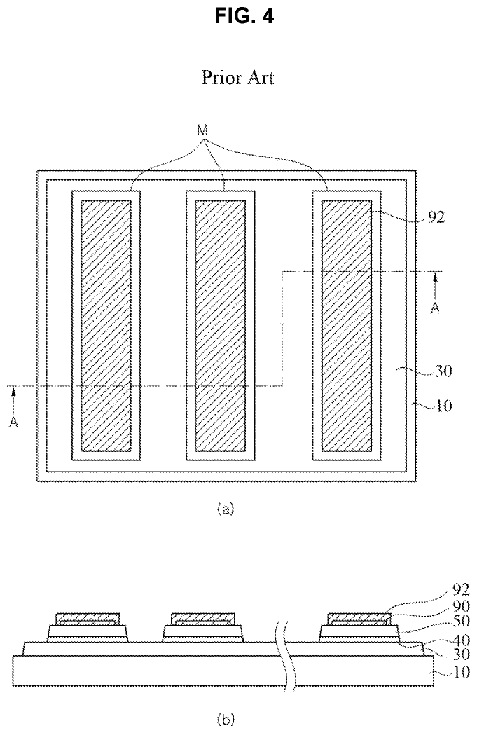

As can be seen from FIG. 6B, the first ohmic electrode 190 is widely formed on the first semiconductor layer 120, and the second ohmic electrode 191 is widely formed on the second semiconductor layers 131, 141 and 151. With the first ohmic electrode 190 and the second ohmic electrode 191 being formed extensively on the first semiconductor layer 120 and the second semiconductor layers 131, 141 and 151, respectively, the current spreading performance can be improved. This is particularly a preferable structure in that in the case of a flip chip that emits light from the active layer towards the growth substrate, a less amount of the ultraviolet light is absorbed by the first and second ohmic electrodes 190 and 191, as compared with the case of a lateral chip. Apart from the above features described with reference to FIG. 6, the semiconductor light emitting device is substantially identical with the one shown in FIG. 4.

FIG. 7 shows an exemplary method for manufacturing a semiconductor light emitting device according to the present disclosure.

First, a growth substrate 200 is prepared (S1). On the growth substrate 200, a semiconductor layer 210, an active layer 220 and a second semiconductor layer 230 are formed (S2). Although not shown, other layers such as a buffer layer may be additionally formed. Next, a first light emitting part 240, a second light emitting part 250 and a connecting part 260 are then formed by etching (S3). In particular, the first light emitting part 240 and the second light emitting part 250 are etched to have a plurality of grooves 241 and 251 therein, respectively. In FIG. 7, once etched, the first semiconductor layer 240 is connected to the active layers of the first light emitting part 240, the second light emitting part 250 and the connecting part 260 without a damp. If the first semiconductor layer 210 is etched further, however, this exposed first semiconductor layer 120 can be connected to the active layers of the first light emitting part 240, the second light emitting part 250 and the connecting part 260 with a dam. Moreover, although the lateral surfaces of the first light emitting part 240, the second light emitting part 250 and the connecting part 260 can be etched vertically as shown in FIG. 7, they may be etched at an angle when seen in a plan view, exposing part of the active layer and hence, increasing the luminous efficiency. An insulating layer 270 that covers the first light emitting part 240, the second light emitting part 250 and the connecting part 260 is formed (S4). Via holes 280, 281 that run through the insulating layer 270 are formed (S5). The via hole 280 is connected to the first semiconductor layer 210, and the via hole 281 is connected to the second semiconductor layer 230. A first and a second pad electrode 290, 291 are formed (S6). The first pad electrode 290 is electrically connected to the first semiconductor layer 210 through the via hole 280, and the second pad electrode 291 is electrically connected to the second semiconductor layer 230 through the via hole 281. Although not shown, an ohmic electrode may be formed between the steps S3 and S4. If the ohmic electrode is present, the via holes 280 and 281 can be connected to the ohmic electrode. A groove 2411 where the via hole 280 connected to the ohmic electrode lies has a width large enough to receive the via hole, while a groove 2412 where the via hole 280 is not present has a width smaller than the width of the via hole 280. In this way, more active layers can be ensured.

Various embodiments of the present disclosure will be described below.

(1) A semiconductor light emitting device comprising: a growth substrate; a first semiconductor layer which is provided on the growth substrate and has a first conductivity; a first light emitting part, including an active layer which is provided on the first semiconductor layer and generates ultraviolet light by electron-hole recombination, and a second semiconductor layer which is provided on the active layer and has a second conductivity different from the first conductivity; a second light emitting part, including an active layer which is provided on the first semiconductor layer and generates ultraviolet light by electron-hole recombination, and a second semiconductor layer which is provided on the active layer and has a second conductivity different from the first conductivity; a connecting part, including an active layer which is provided on the first semiconductor layer and generates ultraviolet light by electron-hole recombination, and a second semiconductor layer which is provided on the active layer and has a second conductivity different from the first conductivity, with the connecting part connecting the first light emitting part and the second light emitting part; an insulating layer that covers the first semiconductor layer, the first light emitting part, the second light emitting part and the connecting part; a first pad electrode which is formed on the insulating layer and is electrically connected to the first semiconductor layer; and a second pad electrode which is formed on the insulating layer and is electrically connected to the second semiconductor layer, wherein, part of the connecting part does not overlap with the first pad electrode and the second pad electrode in a plan view, and the connecting part has a width smaller than the widths of first light emitting part and the second light emitting part.

(2) There is also provided the semiconductor light emitting device of (1), wherein the first light emitting part and the second light emitting part have lateral surfaces, and at least one of the lateral surfaces of the first light emitting part and the second light emitting part includes, in a plan view, a plurality of grooves through which the first semiconductor layer is exposed.

(3) There is also provided the semiconductor light emitting device of (2), wherein the lateral surfaces of the first light emitting part and the second light emitting part include inner lateral surfaces formed in the direction of the connecting part and outer lateral surfaces facing the inner lateral surfaces, and the plurality of grooves is included in the outer lateral surfaces.

(4) There is also provided the semiconductor light emitting device of (3), wherein the outer lateral surface of the first light emitting part as well as the outer lateral surface of the second light emitting part include a plurality of grooves, with the plurality of grooves formed in the outer lateral surface of the first light emitting part as well as the outer lateral surface of the second light emitting part are not uniform in size.

(5) There is also provided the semiconductor light emitting device of (4), comprising: a first ohmic electrode which is positioned under the insulating layer and is electrically connected to the first semiconductor layer, wherein the first ohmic electrode is electrically connected to the first pad electrode, and the first ohmic electrode electrically connected to the first semiconductor layer lies in a groove having the largest width out of the plurality of grooves formed on the outer lateral surface of the first light emitting part.

(6) There is also provided the semiconductor light emitting device of (5), comprising: a second ohmic electrode which is positioned under the insulating layer and is electrically connected to the second semiconductor layer, wherein the second ohmic electrode is electrically connected to the second pad electrode, and the second ohmic electrode electrically connected to the second semiconductor layer is electrically connected to the second semiconductor layer positioned in the second light emitting part.

(7) There is also provided the semiconductor light emitting device of (6), wherein, the first light emitting part is entirely overlapped with the first pad electrode in a plan view, and the second light emitting part is entirely overlapped with the second pad electrode in a plan view.

(8) There is also provided the semiconductor light emitting device of (2), wherein the plurality of grooves has a depth between ½ and ⅔ of the widths of the first and second light emitting parts.

(9) There is also provided the semiconductor light emitting device of (2), wherein a gap between the plurality of grooves is not larger than ½ of the widths of the first and second light emitting parts.

(10) There is also provided the semiconductor light emitting device of (1), wherein the connecting part has a width between 50 μm and 160 μm.

The present disclosure allows to obtain a semiconductor light emitting device of a higher luminous efficiency of ultraviolet light.

What is claimed is:

1. A semiconductor light emitting device comprising:
a growth substrate;
a first semiconductor layer which is provided on the growth substrate and has a first conductivity;
a first light emitting part, including an active layer which is provided on the first semiconductor layer and generates ultraviolet light by electron-hole recombination, and a second semiconductor layer which is provided on the active layer and has a second conductivity different from the first conductivity;
a second light emitting part, including an active layer which is provided on the first semiconductor layer and generates ultraviolet light by electron-hole recombination, and a second semiconductor layer which is provided on the active layer and has a second conductivity different from the first conductivity;
a connecting part, including an active layer which is provided on the first semiconductor layer and generates ultraviolet light by electron-hole recombination, and a second semiconductor layer which is provided on the active layer and has a second conductivity different from the first conductivity, with the connecting part connecting the first light emitting part and the second light emitting part;
an insulating layer that covers the first semiconductor layer, the first light emitting part, the second light emitting part and the connecting part;
a first pad electrode which is formed on the insulating layer and is electrically connected to the first semiconductor layer; and
a second pad electrode which is formed on the insulating layer and is electrically connected to the second semiconductor layer,
wherein, in a plan view, part of the connecting part does not overlap with the first pad electrode and the second pad electrode, and the connecting part has a width smaller than the widths of first light emitting part and the second light emitting part.

2. The semiconductor light emitting device of claim 1, wherein the first light emitting part and the second light emitting part have lateral surfaces, and at least one of the lateral surfaces of the first light emitting part and the second light emitting part includes, in a plan view, a plurality of grooves through which the first semiconductor layer is exposed.

3. The semiconductor light emitting device of claim 2, wherein the lateral surfaces of the first light emitting part and the second light emitting part include inner lateral surfaces formed in the direction of the connecting part and outer lateral surfaces facing the inner lateral surfaces, and the plurality of grooves is included in the outer lateral surfaces.

4. The semiconductor light emitting device of claim 3, wherein the outer lateral surface of the first light emitting part as well as the outer lateral surface of the second light emitting part include a plurality of grooves, with the plurality of grooves formed in the outer lateral surface of the first light emitting part as well as the outer lateral surface of the second light emitting part are not uniform in size.

5. The semiconductor light emitting device of claim 4, comprising:
a first ohmic electrode which is positioned under the insulating layer and is electrically connected to the first semiconductor layer,
wherein the first ohmic electrode is electrically connected to the first pad electrode, and
the first ohmic electrode electrically connected to the first semiconductor layer lies in a groove having the largest width out of the plurality of grooves formed on the outer lateral surface of the first light emitting part.

6. The semiconductor light emitting device of claim 5, comprising:
a second ohmic electrode which is positioned under the insulating layer and is electrically connected to the second semiconductor layer,
wherein the second ohmic electrode is electrically connected to the second pad electrode, and
the second ohmic electrode electrically connected to the second semiconductor layer is electrically connected to the second semiconductor layer positioned in the second light emitting part.

7. The semiconductor light emitting device of claim 6, wherein the first light emitting part is entirely overlapped with the first pad electrode in a plan view, and the second light emitting part is entirely overlapped with the second pad electrode in a plan view.

8. The semiconductor light emitting device of claim 2, wherein the plurality of grooves has a depth between ½ and ⅔ of the widths of the first and second light emitting parts.

9. The semiconductor light emitting device of claim 2, wherein a gap between the plurality of grooves is not larger than ½ of the widths of the first and second light emitting parts.

10. The semiconductor light emitting device of claim 1, wherein the connecting part has a width between 50 μm and 160 μm.
